(19) United States
(12) Patent Application Publication
(10) Pub. No.: US 2025/0372973 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/215,336

(22) Filed: May 22, 2025

(30) Foreign Application Priority Data
May 29, 2024 (JP) 2024-087278

(51) Int. Cl. H02G 3/08; B60R 16/023; H01R 25/16

(52) U.S. Cl. CPC H02G 3/081; B60R 16/0239; H01R 25/165; H01R 2201/26

(57) ABSTRACT

An electrical connection unit includes a first subunit having a plurality of first bus bars, and a first base member including a plate-shaped or sheet-shaped first flat surface portion and a first positioning portion, and a second subunit having a plurality of second bus bars, and a second base member including a plate-shaped or sheet-shaped second flat surface portion and a second positioning portion, the second subunit being electrically connected to the first subunit, in which the first positioning portion has a first facing surface extending in a first direction from a first base end of the first flat surface portion on the second subunit side, and the second positioning portion has a second facing surface facing the first facing surface and extending in the first direction along the first facing surface from a second base end of the second flat surface portion on the first subunit side.

### BACKGROUND OF THE INVENTION

### Field of the Invention

Embodiments of the present invention relate to an electrical connection unit.

Priority is claimed on Japanese Patent Application No. 2024-087278 filed in Japan on May 29, 2024, the content of which is incorporated herein by reference.

### Description of the Related Art

An electrical connection unit having a housing that accommodates electronic components and a bus bar attached to the housing in a standing posture is known.
[Patent Document 1] Japanese Unexamined Patent Application, First Publication No. 2024-037492

### SUMMARY OF THE INVENTION

It is expected to improve assemblability of an electrical connection unit.

An embodiment provides an electrical connection unit capable of improving assemblability.

According to an embodiment, there is provided an electrical connection unit including a first subunit including a plurality of first bus bars including portions disposed on the same plane, and a first base member including a plate-shaped or sheet-shaped first flat surface portion holding the plurality of first bus bars, and a first positioning portion; and a second subunit electrically connected to the first subunit and including a plurality of second bus bars including portions disposed on the same plane, and a second base member including a plate-shaped or sheet-shaped second flat surface portion holding the plurality of second bus bars, and a second positioning portion, in which, in a case where a thickness direction of the first flat surface portion is a first direction and a direction intersecting the first direction is a second direction, the first positioning portion has a first facing surface extending in the first direction from a first base end of the first flat surface portion on the second subunit side, and the second positioning portion has a second facing surface facing the first facing surface and extending in the first direction along the first facing surface from a second base end of the second flat surface portion on the first subunit side.

According to one embodiment, assemblability can be improved.

### BRIEF DESCRIPTION OF THE DRAWINGS

FIG. 1 is a cross-sectional view illustrating an electrical connection unit according to an embodiment;

FIG. 2 is a perspective view for describing a main body of the embodiment;

FIG. 3 is a partially exploded perspective view of the electrical connection unit according to the embodiment;

FIG. 4 is a perspective view illustrating a first routing board according to the embodiment;

FIG. 5 is a plan view illustrating the first routing board according to the embodiment;

FIG. 6 is a side view of a first base member of the embodiment;

FIG. 7 is a perspective view illustrating a second routing board according to the embodiment;

FIG. 8 is a plan view illustrating the second routing board according to the embodiment;

FIG. 9 is a side view of a second base member of the embodiment;

FIG. 10 is a cross-sectional view for describing a method of manufacturing the electrical connection unit of the embodiment;

FIG. 11 is a cross-sectional view for describing the method of manufacturing the electrical connection unit of the embodiment;

FIG. 12 is a cross-sectional view for describing the method of manufacturing the electrical connection unit of the embodiment; and

FIG. 13 is a perspective view illustrating a first routing board according to a modification example of the embodiment.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively. The “sheet-shaped” or “sheet” is not limited to a member having a thickness of 1 mm or more, and a member (so-called a film) having a thickness of less than 1 mm can also be used.

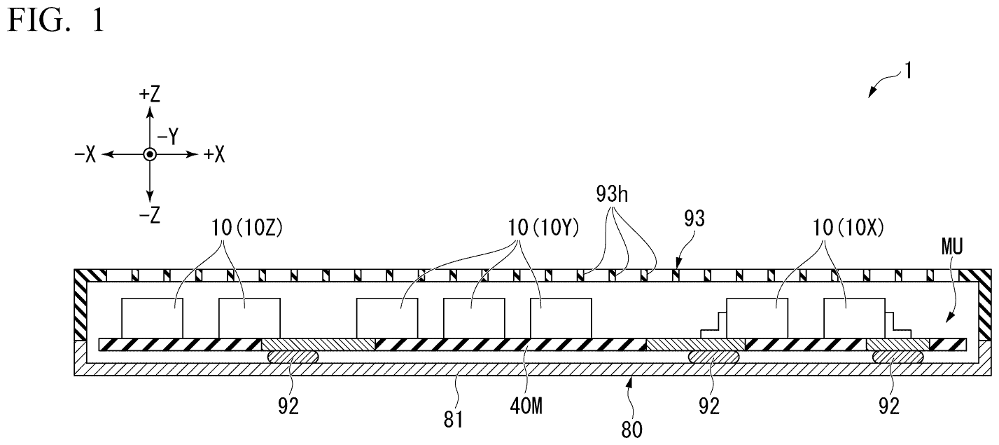

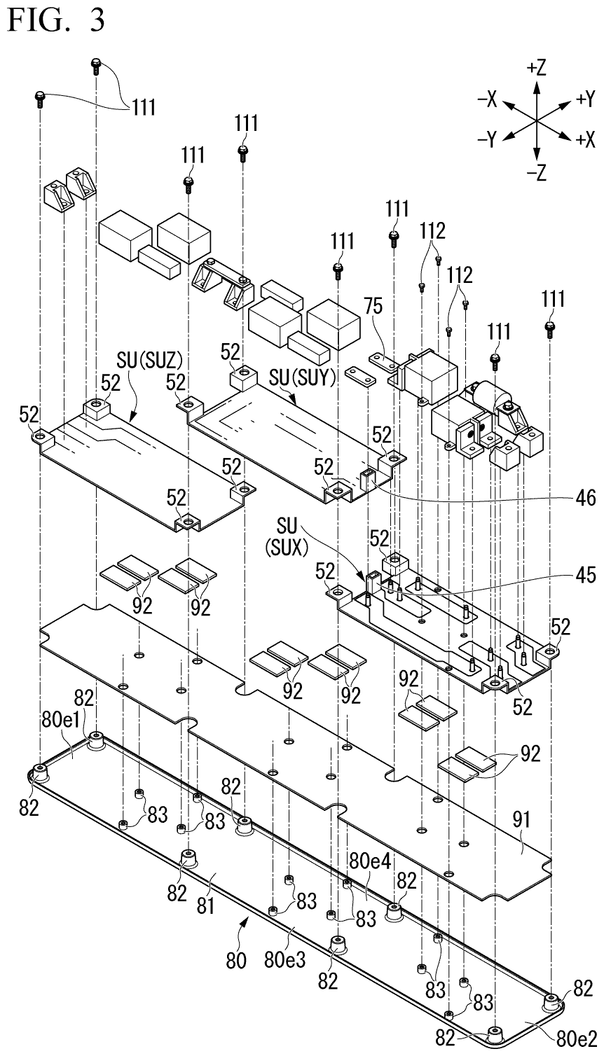

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 3). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 3). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”. The X direction is an example of a “second direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### Embodiment

### 1. Constitution of Electrical Connection Unit

FIG. 1 is a cross-sectional view illustrating an electrical connection unit 1 of the present embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples.

The electrical connection unit 1 includes, for example, a main body MU, a metal plate 80, an insulating sheet 91 (see FIG. 3), a plurality of heat transfer members 92, and an insulating cover 93.

### 2. Main Body

First, the main body MU will be described.

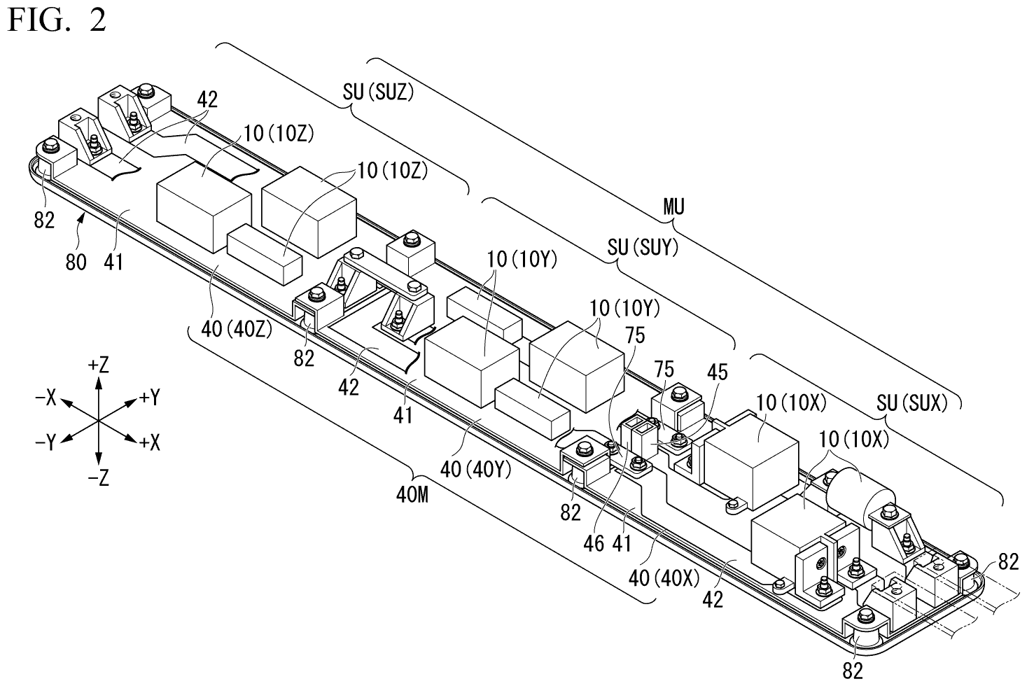

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting a plurality of subunits SU. In the present embodiment, the main body MU includes three subunits SU (a subunit SUX, a subunit SUY, and a subunit SUZ). Each subunit SU may be referred to as a “circuit constitution body”.

The subunit SUX has an electrical first function. The subunit SUX includes, for example, a plurality of electronic components 10X and a first routing board 40X. The plurality of electronic components 10X are electrically connected to the first routing board 40X.

The subunit SUY has an electrical second function. The second function is a function different from the first function. The subunit SUY includes, for example, a plurality of electronic components 10Y and a second routing board 40Y. The plurality of electronic components 10Y are electrically connected to the second routing board 40Y.

The subunit SUZ has an electrical third function. The third function is a function different from the first function and the second function. The subunit SUZ includes, for example, a plurality of electronic components 10Z and a third routing board 40Z. The plurality of electronic components 10Z are electrically connected to the third routing board 40Z.

In the present embodiment, the three subunits SUX, SUY, and SUZ are disposed to be arranged in the X direction. For example, the subunit SUX is disposed on the +X direction side with respect to the subunit SUY. The subunit SUX and the subunit SUY are electrically connected via a plurality of coupling bus bars 75 extending between the first routing board 40X and the second routing board 40Y. On the other hand, the subunit SUZ is disposed on the −X direction side with respect to the subunit SUY.

In the present embodiment, the three routing boards (the first routing board 40X, the second routing board 40Y, and the third routing board 40Z) included in the three subunits SUX, SUY, and SUZ are disposed on the same plane. In other words, the three routing boards (the first routing board 40X, the second routing board 40Y, and the third routing board 40Z) are disposed at the same height position in the Z direction. One large routing board 40M is formed by disposing the three routing boards (the first routing board 40X, the second routing board 40Y, and the third routing board 40Z). Note that two or more subunits SU are not limited to subunits SU having different functions, and may be the subunits SU having the same function.

Each subunit SU includes, for example, a plurality of electronic components 10 and a routing board 40. The routing board 40 includes, for example, a base plate 41, a plurality of bus bars 42, and a plurality of fastening members 43. A detailed constitution of each subunit SU will be described later.

### 3. Metal Plate

FIG. 3 is a partially exploded perspective view of the electrical connection unit 1. The metal plate 80 is a member for securing rigidity of the electrical connection unit 1 and enhancing a heat dissipation property of the electrical connection unit 1. The metal plate 80 is made of a metal (for example, aluminum or an aluminum alloy). The metal plate 80 may be referred to as a “rigid member”.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of end portions of the metal plate 80 in the longitudinal direction, and are separated in the X direction. The third end 80e3 and the fourth end 80e4 are a pair of end portions of the metal plate 80 in the lateral direction, and are separated in the Y direction. The metal plate 80 includes, for example, a flat surface portion 81, a plurality of fixing portions 82, and a plurality of fixing portions 83.

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the three subunits SU from below. The flat surface portion 81 faces the routing boards 40 of the three subunits SU.

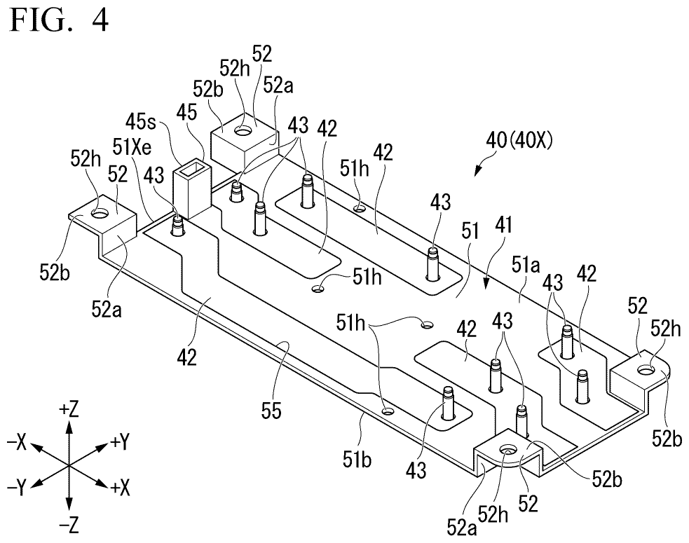

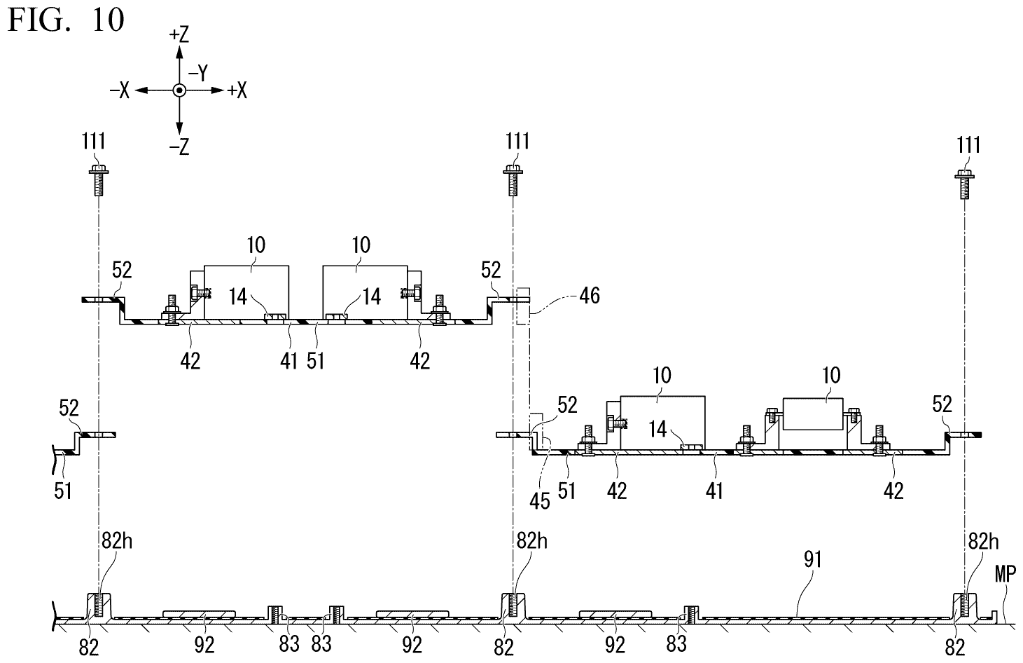

The fixing portion 82 is a boss protruding in the +Z direction from the flat surface portion 81 of the metal plate 80. For example, the fixing portion 82 protrudes to the +Z direction side from a first surface 51a (see FIG. 4) of the flat surface portion 51 of the base plate 41. In the present embodiment, the fixing portion 82 protrudes more in the +Z direction than the fixing portion 83. The fixing portion 82 faces the fixing portion 52 of the base plate 41 in the Z direction. The fixing portion 82 has an engagement hole 82h (see FIG. 10) that is open in the +Z direction. An inner circumferential surface of the engagement hole 82h has a screw groove.

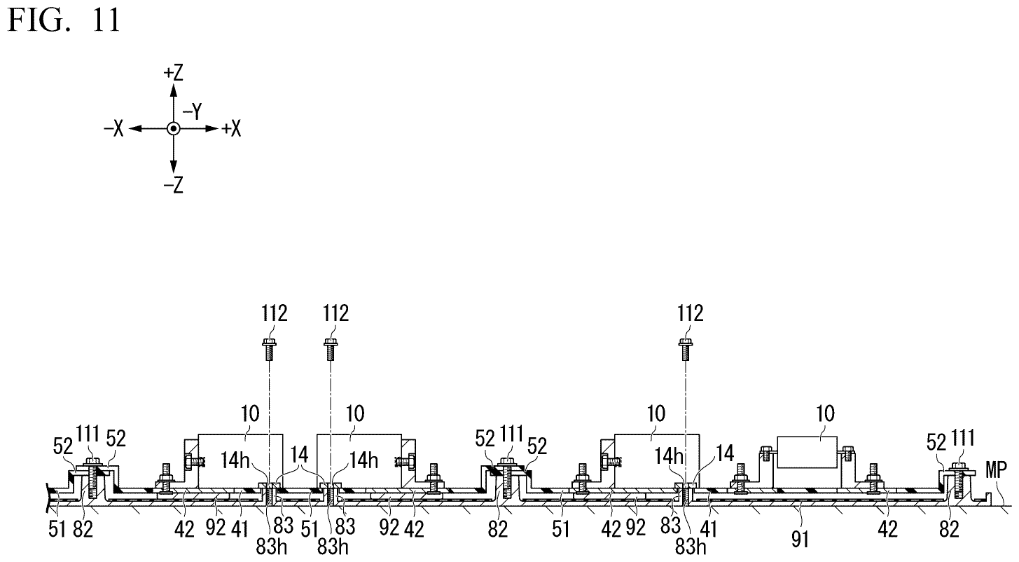

The fixing portion 83 is a boss protruding in the +Z direction from the flat surface portion 81. The fixing portion 83 is inserted into a through-hole 51h (see FIG. 4) of the flat surface portion 51 of the base plate 41. For example, the fixing portion 83 passes through the through-hole 51h of the flat surface portion 51 and protrudes to a position beyond the first surface 51a of the flat surface portion 51 (a position on the +Z direction side with respect to the first surface 51a). The fixing portion 83 faces an attachment portion 14 (see FIG. 11) of the electronic component 10 in the Z direction. The fixing portion 83 has an engagement hole 83h that is open in the +Z direction. An inner circumferential surface of the engagement hole 83h has a screw groove.

A fastening member 112 (for example, a screw or a bolt) passes through the attachment hole 14h (see FIG. 11) of the attachment portion 14 of the electronic component 10 from the +Z direction side. When the fastening member 112 that has passed through the attachment hole 14h of the attachment portion 14 of the electronic component 10 is engaged with the engagement hole 83h of the fixing portion 83 of the metal plate 80, the electronic component 10 is fixed to the metal plate 80 without passing through the base plate 41. Here, the attachment hole 14h is open in the Z direction. The attachment hole 14h is an insertion hole through which the fastening member 112 passes. The fastening member 112 is an example of a “second fastening member”.

### 4. Insulating Sheet

The insulating sheet 91 is an insulating member for electrically insulating the metal plate 80 and the bus bar 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between the flat surface portion 81 of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding the fixing portion 82 and the fixing portion 83 of the metal plate 80. Note that, instead of the above example, the insulating sheet 91 may be provided between the routing board 40 of each subunit SU and the plurality of heat transfer members 92.

### 5. Heat Transfer Member

The heat transfer member 92 is a member for transferring heat generated by the electronic component 10 at the time of energization and/or heat generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

### 6. Insulating Cover

Referring to FIG. 1 again, the insulating cover 93 will be described. The insulating cover 93 is a member for securing safety of the main body MU with respect to the energization path. The insulating cover 93 is made of, for example, a synthetic resin and has an insulating property. The insulating cover 93 has, for example, a box shape that is open on the −Z direction side. The insulating cover 93 has a plurality of vent holes 93h. The insulating cover 93 is attached along the metal plate 80 on the +Z direction side of the metal plate 80. Note that the insulating cover 93 is not limited to a box-shaped member, and may be a sheet-shaped member that covers the energization path of the main body MU.

<7. Detailed Constitution of Subunit>

Next, a constitution of the subunit SU will be described.

In the present embodiment, the three subunits SUX, SUY, and SUZ have the same or similar basic structure. Hereinafter, the subunit SUX will be described in detail as a representative. In addition, in a case where the subunit SUX, the subunit SUY, and the subunit SUZ are not distinguished, the subunits will be simply referred to as “subunit SU”. In addition, in a case where the electronic component 10X, the electronic component 10Y, and the electronic component 10Z are not distinguished, the electronic components are simply referred to as “electronic component 10”. In a case where the first routing board 40X, the second routing board 40Y, and the third routing board 40Z are not distinguished, the routing boards are simply referred to as “routing board 40”. The subunit SUX is an example of a “first subunit”. The subunit SUY is an example of a “second subunit”.

### 7.1 Electronic Component

First, the electronic component 10 will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization.

### 7.2 Routing Board (Common Constitution)

Next, the routing board 40 will be described.

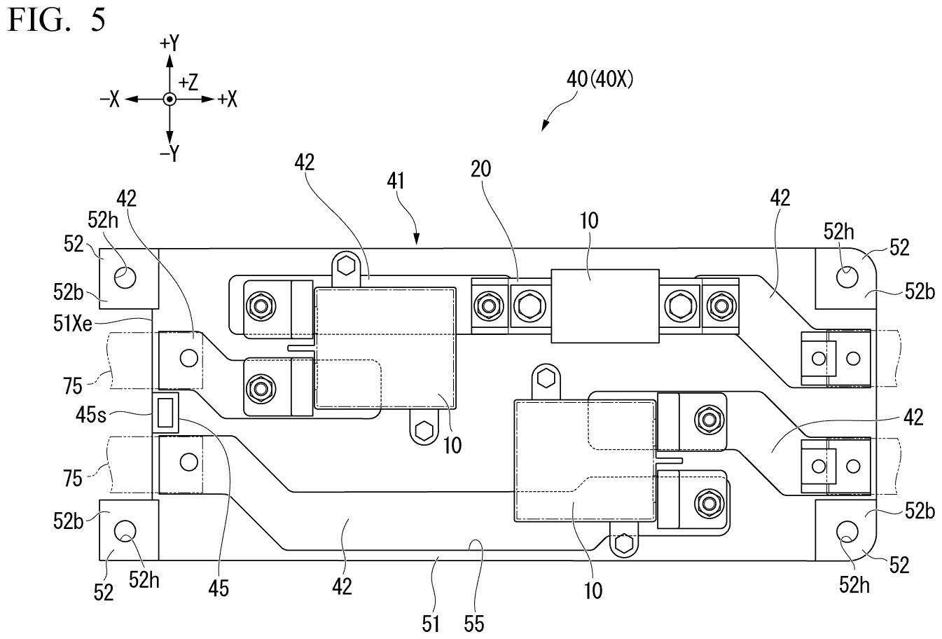

FIG. 4 is a perspective view of the first routing board 40X of the subunit SUX. FIG. 5 is a plan view of the first routing board 40X of the subunit SUX. Each constitution of the first routing board 40X illustrated in FIGS. 4 and 5 includes a constitution common to the first routing board 40X, the second routing board 40Y, and the third routing board 40Z and a constitution specific to the first routing board 40X. Hereinafter, the constitution common to the first routing board 40X, the second routing board 40Y, and the third routing board 40Z will be described with reference to FIGS. 4 and 5 for convenience. Further, the constitution specific to the subunit SUX will be described with reference to FIGS. 4 and 5 while expressing the specific constitution.

The routing board 40 is a member that forms at least part of an energization path between the plurality of electronic components 10 and/or at least part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. As illustrated in FIGS. 4 and 5, in the present embodiment, the routing board 40 has a plate shape formed in the X direction and the Y direction.

As described above, the routing board 40 includes, for example, the base plate 41, the plurality of bus bars 42, and the plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board may be formed by another structure instead of the insert molding.

### (Base Plate)

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 is an example of a “base member”. The base plate 41 may be referred to as an “insulating substrate”. The base plate 41 includes, for example, a flat surface portion 51 and a plurality of fixing portions 52.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 forms a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41.

The flat surface portion 51 has a first surface 51a and a second surface 51b. The first surface 51a is a surface directed in the +Z direction. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed in the −Z direction. The second surface 51b is a flat surface provided in the horizontal direction. The second surface 51b faces the metal plate 80 (see FIG. 1). A thickness direction (plate thickness direction) of the flat surface portion 51 is the Z direction.

The flat surface portion 51 has a through-hole 51h. The through-hole 51h penetrates the flat surface portion 51 in the Z direction. The through-hole 51h is provided at a position corresponding to a fixing portion 83 of the metal plate 80 that will be described later when viewed from the Z direction. The fixing portion 83 of the metal plate 80 passes through the through-hole 51h of the base plate 41 and protrudes to the +Z direction side from the first surface 51a of the flat surface portion 51. The attachment portion 14 of the electronic component 10 is fixed to the fixing portion 83 on the first surface 51a side of the flat surface portion 51.

Each fixing portion 52 includes, for example, a standing plate portion 52a and a horizontal plate portion 52b.

The standing plate portion 52a stands in the +Z direction from the end of the flat surface portion 51 of the base plate 41. The standing plate portion 52a is a plate portion provided in the Y direction and the Z direction. The thickness direction of the standing plate portion 52a is the X direction.

The horizontal plate portion 52b extends in the horizontal direction from the end of the standing plate portion 52a in the +Z direction. The horizontal plate portion 52b is a plate portion provided in the horizontal direction. The horizontal plate portion 52b faces the fixing portion 82 of the metal plate 80 in the Z direction. The horizontal plate portion 52b has an insertion hole 52h facing the engagement hole 82h of the fixing portion 82 of the metal plate 80. As illustrated in FIG. 3, a fastening member 111 (for example, a screw or a bolt) passes through the insertion hole 52h. When the fastening member 111 that has passed through the insertion hole 52h of the fixing portion 52 of the base plate 41 is engaged with the engagement hole 82h of the fixing portion 82 of the metal plate 80, the base plate 41 is fixed to the metal plate 80. The fastening member 111 is an example of a “first fastening member”.

### (Bus Bar)

Each bus bar 42 is a routing member (electrical connection member) included in the routing board 40. The bus bar 42 is, for example, a routing member for electrically connecting the plurality of electronic components 10. Alternatively, each bus bar 42 may be a routing member for connecting the electronic component 10 to an external device. Each of the bus bars 42 is made of a metal (for example, copper or a copper alloy) and has conductivity. The plurality of bus bars 42 are disposed to be arranged in the horizontal direction at intervals. The plurality of bus bars 42 include portions disposed on the same plane. The plurality of bus bars 42 are held by the flat surface portion 51 of the base plate 41.

As illustrated in FIGS. 4 and 5, at least part of each bus bar 42 has a plate shape formed in the horizontal direction. At least part of each bus bar 42 is accommodated in the accommodation portion 55 and extends along the flat surface portion 51. That is, at least part of each bus bar 42 extends along the first surface 51a of the flat surface portion 51. At least part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51.

### (Fastening Member)

The fastening member 43 is a component for fixing the bus bar 42 and a connection target component (the coupling bus bar 75, a connection component for connection with the terminal of electronic component 10, or a connection component for connection with an external device) of the bus bar 42. The fastening member 43 is, for example, a caulking bolt fixed to the bus bar 42. The fastening member 43 is an example of a “fastening portion”.

### 7.3 First Routing Board (Specific Constitution)

Next, a structure specific to the first routing board 40X will be described.

Here, the bus bar 42 of the first routing board 40X is an example of a “first bus bar”. The base plate 41 of the first routing board 40X is an example of a “first base member”. The flat surface portion 51 of the first routing board 40X is an example of a “first flat surface portion”. The standing plate portion 52a of the first routing board 40X is an example of a “first portion”. The horizontal plate portion 52b of the first routing board 40X is an example of a “second portion”.

As illustrated in FIGS. 4 and 5, the base plate 41 of the first routing board 40X further includes a first positioning portion 45. The first positioning portion 45 has a first facing surface 45s that is a flat surface directed in the −X direction. The first positioning portion 45 has a rectangular tube shape extending in the Z direction with the first facing surface 45s as a part of the outer peripheral surface. Specifically, the first positioning portion 45 has a rectangular tube shape with the first facing surface 45s as an outer peripheral flat surface on the −X direction side. The first facing surface 45s is provided at a first base end 51Xe which is an end portion on the −X side (subunit SUY side) of the flat surface portion 51 of the first routing board 40X. The first positioning portion 45 is disposed between a pair of coupling bus bars 75 arranged apart from each other in the Y direction that will be described later.

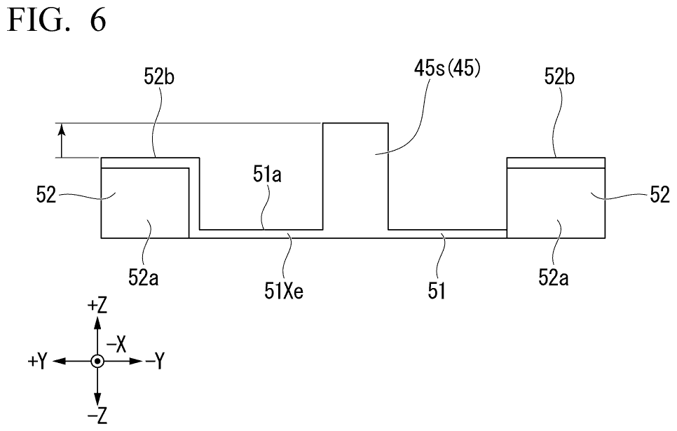

As illustrated in FIG. 6, the first facing surface 45s extends in the +Z direction from the first base end 51Xe. That is, the first facing surface 45s extends from the first base end 51Xe to the side opposite to the metal plate 80. Specifically, the first facing surface 45s extends in the +Z direction to protrude from the first surface 51a of the flat surface portion 51 of the first routing board 40X at the first base end 51Xe. For example, the first facing surface 45s may be flush with an end surface of the first base end 51Xe directed in the −X direction.

The first facing surface 45s protrudes more in the +Z direction than a pair of fixing portions 52 provided to be arranged in the Y direction on the first base end 51Xe side among the plurality of fixing portions 52 of the base plate 41 of the first routing board 40X. Here, each fixing portion 52 on the first base end 51Xe side stands in the +Z direction over the standing plate portion 52a and the horizontal plate portion 52b, and extends in the −X direction in the XY plane from the standing end.

### 7.4 Second Routing Board (Specific Constitution)

Next, a structure specific to the second routing board 40Y will be described.

Here, the bus bar 42 of the second routing board 40Y is an example of a “second bus bar”. The base plate 41 of the second routing board 40Y is an example of a “second base member”. The flat surface portion 51 of the second routing board 40Y is an example of a “second flat surface portion”. The standing plate portion 52a of the second routing board 40Y is an example of a “third portion”. The horizontal plate portion 52b of the second routing board 40Y is an example of a “fourth portion”.

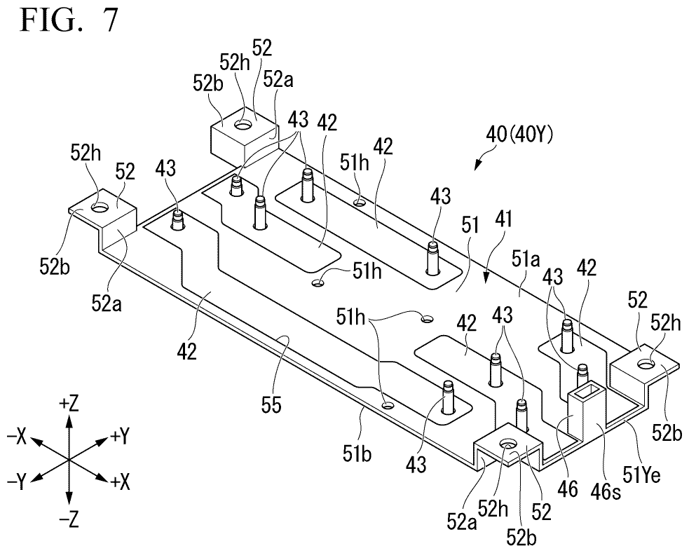

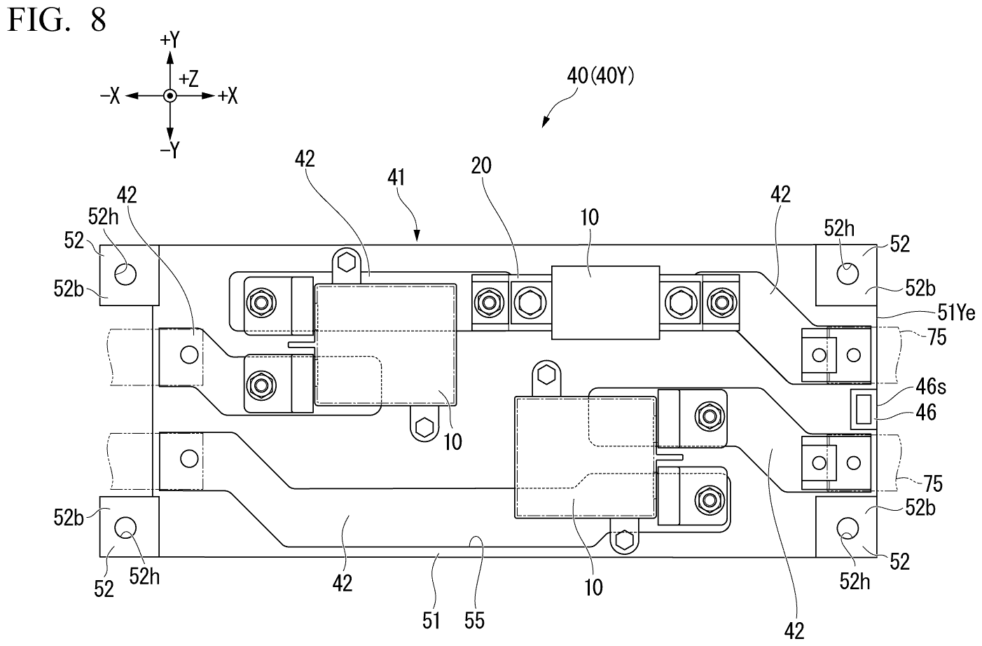

As illustrated in FIGS. 7 and 8, the base plate 41 of the second routing board 40Y further includes a second positioning portion 46. The second positioning portion 46 has a second facing surface 46s that is a flat surface directed in the +X direction. The second positioning portion 46 has a rectangular tube shape extending in the Z direction with the second facing surface 46s as a part of the outer peripheral surface. Specifically, the second positioning portion 46 has a rectangular tube shape with the second facing surface 46s as an outer peripheral flat surface on the +X direction side. The second facing surface 46s is provided at the second base end 51Ye that is an end portion on the +X side (subunit SUX side) of the flat surface portion 51 of the second routing board 40Y. The second positioning portion 46 is disposed between a pair of coupling bus bars 75 arranged apart from each other in the Y direction that will be described later.

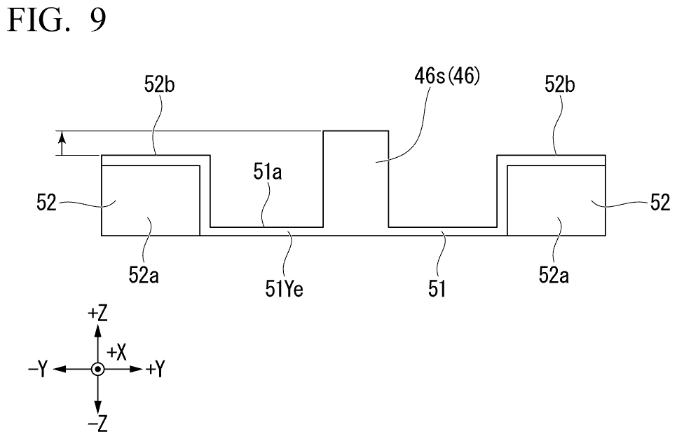

As illustrated in FIG. 9, the second facing surface 46s extends in the +Z direction from the second base end 51Ye to face the first facing surface 45s and extend along the first facing surface 45s. That is, the second facing surface 46s extends from the second base end 51Ye to the side opposite to the metal plate 80. Specifically, the second facing surface 46s extends in the +Z direction to protrude from the first surface 51a of the flat surface portion 51 of the second routing board 40Y at the second base end 51Ye. For example, the second facing surface 46s may be flush with the end surface of the second base end 51Ye directed in the +X direction. For example, the second facing surface 46s and the first facing surface 45s may have the same shape and the same size.

The second facing surface 46s protrudes more in the +Z direction than a pair of fixing portions 52 provided to be arranged in the Y direction on the second base end 51Ye side among the plurality of fixing portions 52 of the base plate 41 of the second routing board 40Y. Here, each fixing portion 52 on the second base end 51Ye side stands in the +Z direction over the standing plate portion 52a and the horizontal plate portion 52b, and extends in the +X direction in the XY plane from the standing end.

### 7.5 Fixing Structure Related to Plurality of Subunits

Next, referring to FIG. 2 again, a fixing structure related to the plurality of subunits SU will be described. In the present embodiment, the main body MU is divided into a plurality of subunits SU (for example, the subunit SUX, the subunit SUY, and the subunit SUZ).

The subunit SUX includes the plurality of electronic components 10X, the base plate 41, and the plurality of bus bars 42. The plurality of bus bars 42 include portions disposed on the same plane, and are electrically connected to the plurality of electronic components 10X. The electronic components 10X is an example of a “first electronic component”.

The subunit SUY includes the plurality of electronic components 10Y, the base plate 41, and the plurality of bus bars 42. The plurality of bus bars 42 include portions disposed on the same plane, and are electrically connected to the plurality of electronic components 10Y. The subunit SUY is electrically connected to the subunit SUX via, for example, a pair of coupling bus bars 75 each extending in the X direction and arranged apart from each other in the Y direction. The electronic component 10Y is an example of a “second electronic component”.

The subunit SUZ includes the plurality of electronic components 10Z, the base plate 41, and the plurality of bus bars 42. The plurality of bus bars 42 include portions disposed on the same plane, and are electrically connected to the plurality of electronic components 10Z. The subunit SUZ is an example of a “third subunit”. The electronic component 10Z is an example of a “third electronic component”. The base plate 41 of the subunit SUZ is an example of a “third base member”. The flat surface portion 51 of the base plate 41 of the subunit SUZ is an example of a “third flat surface portion”.

In the present embodiment, each of the plurality of subunits SU (for example, three subunits SUX, SUY, and SUZ) is fixed to the metal plate 80. With this fixation, the plurality of subunits SU (for example, three subunits SUX, SUY, and SUZ) are integrally held by one metal plate 80.

In the present embodiment, the longitudinal direction of the subunit SUX is the X direction. The longitudinal direction of the subunit SUY is the X direction. The longitudinal direction of the subunit SUZ is the X direction. The plurality of subunits SU (for example, three subunits SUX, SUY, and SUZ) are adjacent to each other in the X direction and are arranged in a line in the X direction. The longitudinal direction of the metal plate 80 is the X direction. The length of the metal plate 80 in the X direction is larger than the sum of the lengths of the plurality of subunits SU (for example, three subunits SUX, SUY, and SUZ) in the X direction.

In the present embodiment, the fixing portion 52 of the subunit SUX and the fixing portion 52 of the subunit SUY are disposed at positions overlapping each other in the Z direction. The fixing portion 52 of the subunit SUX and the fixing portion 52 of the subunit SUY are collectively fixed to the fixing portion 82 of the metal plate 80 via one fastening member 111. The fixing portion 52 of the subunit SUX is an example of a “first fixing portion”. The fixing portion 52 of the subunit SUY is an example of a “second fixing portion”.

Similarly, the fixing portion 52 of the subunit SUY and the fixing portion 52 of the subunit SUZ are disposed at positions overlapping each other in the Z direction. The fixing portion 52 of the subunit SUY and the fixing portion 52 of the subunit SUZ are collectively fixed to the fixing portion 82 of the metal plate 80 by one fastening member 111.

In the present embodiment, heat generated by the electronic component 10X and the bus bar 42 included in the subunit SUX is transferred to the metal plate 80 via the one or more heat transfer members 92 facing the subunit SUX. Similarly, heat generated by the electronic component 10Y and the bus bar 42 included in the subunit SUY is transferred to the metal plate 80 via the one or more heat transfer members 92 facing the subunit SUY. Heat generated by the electronic components 10Z and the bus bars 42 included in the subunit SUZ is transferred to the metal plate 80 via the one or more heat transfer members 92 facing the subunit SUZ. The plurality of subunits SU (for example, three subunits SUX, SUY, and SUZ) have different amounts of heat generation, for example.

In the present embodiment, the cooling of the plurality of subunits SU (for example, three subunits SUX, SUY, and SUZ) can be promoted by one large metal plate 80. For example, in a case where the amounts of heat generation of the plurality of subunits SU are different, the heat of the plurality of subunits SU can be equalized by one large metal plate 80.

### 8. Method of Manufacturing Electrical Connection Unit

Next, a method of manufacturing the electrical connection unit 1 will be described.

FIGS. 10 to 12 are cross-sectional views for describing the method of manufacturing the electrical connection unit 1. In the routing board 40 of each subunit SU, the base plate 41 and the plurality of bus bars 42 are integrated through insert molding or another method in a state in which the fastening member 43 is fixed to the bus bars 42. Such integration allows the routing board 40 of each subunit SU to be prepared in advance.

### (First Step)

FIG. 10 illustrates a first step. In the first step, each subunit SU is attached to the metal plate 80 placed on a placement table MP. The first step is performed, for example, as follows. First, the insulating sheet 91 (see FIG. 3) is attached to the surface of the flat surface portion 81 of the metal plate 80. Next, the heat transfer member 92 is fixed to the lower surface of each subunit SU with an adhesive or the like. Next, each subunit SU is placed on the metal plate 80 with the insulating sheet 91 and the heat transfer member 92 interposed therebetween. The fixing portion 52 of each subunit SU is fixed to the fixing portion 82 of the metal plate 80 via the fastening member 111.

### (Second Step)

FIG. 11 illustrates a second step. In the second step, the attachment portion 14 of the electronic component 10 of each subunit SU is fixed to the fixing portion 83 of the metal plate 80 via the fastening member 112. The first step may be performed together with the second step.

### (Third Step)

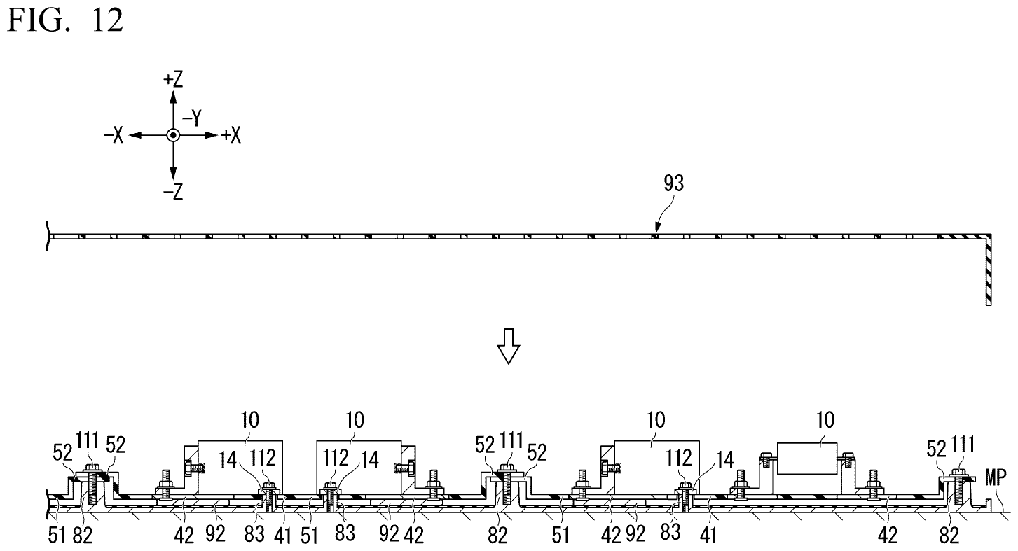

FIG. 12 illustrates a third step. In the third step, the insulating cover 93 is attached to the metal plate 80 in the vertical direction. This attachment completes the electrical connection unit 1.

### 9. Advantages

According to the present embodiment, the second facing surface 46s faces the first facing surface 45s and extends in the Z direction along the first facing surface 45s. According to such a constitution, the position of the subunit SUY that is a second subunit adjacent to the subunit SUX that is a first subunit can be physically defined. With this definition, according to the present embodiment, it is easy to align the subunits SU. Therefore, assemblability can be improved. For example, since the subunit SUY can be installed while the second facing surface 46s comes into contact with the first facing surface 45s of the installed subunit SUX, it is easy to assemble the subunits SU.

According to the present embodiment, the height of the first facing surface 45s from the flat surface portion 51 is larger than the height of the fixing portion 52 from the flat surface portion 51. With such a constitution, when the subunit SUY is installed from the end from which the first facing surface 45s extends, the first facing surface 45s comes into contact with the second facing surface 46s before the fixing portion 52 comes into contact with the subunit SUY. Therefore, it is easy to align the subunits SU.

According to the present embodiment, the first facing surface 45s and the second facing surface 46s extend to the side opposite to the metal plate 80. With such a constitution, it is possible to install the subunit SUY toward the metal plate 80 with respect to the subunit SUX installed on the metal plate 80 while making the second facing surface 46s follow the first facing surface 45s. Therefore, it is easy to align the subunits SU on the metal plate 80.

According to the present embodiment, the first positioning portion 45 has a rectangular tube shape extending in the Z direction. With such a structure, the mechanical strength of the first positioning portion 45 can be improved. In addition, with such a structure, heat of the routing board 40 can be rectified upward and dissipated by using the hollow space and the outer peripheral space of the first positioning portion 45 extending in the direction away from the base plate 41.

According to the present embodiment, the first positioning portion 45 is disposed between the pair of coupling bus bars 75. With such a constitution, a space between the pair of coupling bus bars 75 can be effectively used. Therefore, the electrical connection unit 1 can be miniaturized. With such a constitution, an electrical insulation distance between the pair of coupling bus bars 75 can be secured.

### 10. Modification Examples

Next, several modification examples will be described. Note that a constitution other than those described below in each modification example is the same as the constitution of the above-described embodiment.

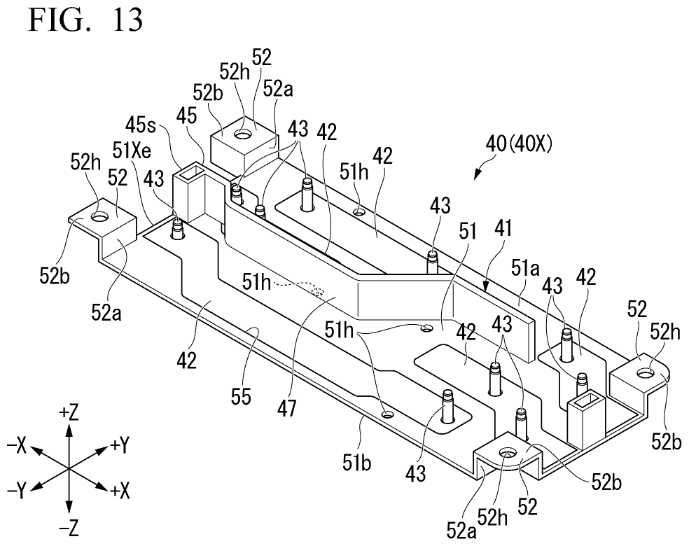

In the above-described embodiment, the first routing board 40X includes the first positioning portion 45 protruding in the +Z direction. However, as long as alignment between the subunits SU can be performed, a structure of the first positioning portion 45 protruding in the +Z direction may be used together with other functions. As a modification example, as illustrated in FIG. 13, the first positioning portion 45 may be connected to an extending end of the insulating rib 47 of the base plate 41 of the subunit SUX. Here, the insulating rib 47 is a wall standing from the first surface 51a of the flat surface portion 51 and extending along the first surface 51a. The insulating rib 47 may extend between the plurality of electronic components 10X.

In the above-described embodiment, the first positioning portion 45 has a rectangular tube shape. However, the subunits SU may be formed in any shape as long as the subunits SU can be aligned with each other. As a modification example, the first positioning portion 45 may have a prismatic shape in which the first facing surface 45s is an outer peripheral flat surface on the −X direction side. As a modification example, the first positioning portion 45 may have a plate shape in which the first facing surface 45s is a plate surface on the −X direction side.

In the above-described embodiment, the second positioning portion 46 has a rectangular tube shape. However, the subunits SU may be formed in any shape as long as the subunits SU can be aligned with each other. As a modification example, the second positioning portion 46 may have a prismatic shape in which the second facing surface 46s is an outer peripheral flat surface on the −X direction side. As a modification example, the second positioning portion 46 may have a plate shape in which the second facing surface 46s is a plate surface on the −X direction side.

In the above-described embodiment, the first facing surface 45s is flush with the end surface of the first base end 51Xe directed in the −X direction. However, the subunits SU may be formed in any shape as long as the subunits SU can be aligned with each other. As a modification example, the first facing surface 45s and the end surface of the first base end 51Xe directed in the −X direction may be shifted in the X direction.

In the above-described embodiment, the second facing surface 46s is flush with the end surface of the second base end 51Ye directed in the +X direction. However, the subunits SU may be formed in any shape as long as the subunits SU can be aligned with each other. As a modification example, the second facing surface 46s and the end surface of the second base end 51Ye directed in the +X direction may be shifted in the X direction.

In the above-described embodiment, the first facing surface 45s and the second facing surface 46s are flat surfaces. However, the subunits SU may be formed in any shape as long as the subunits SU can be aligned with each other. As a modification example, the first facing surface 45s and the second facing surface 46s may be curved surfaces that can be brought into surface contact with each other. For example, the first facing surface 45s and the second facing surface 46s may be curved surfaces extending straight in the Z direction that can be brought into surface contact with each other.

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by part of the flat surface portion 51 following the outer shape of the bus bar 42.

A connection between the electronic component 10 and the bus bar 42 is not limited to the connection using the connection component 20. The electronic component may be directly connected to the bus bar 42 by using a fastening member (for example, a bolt or a screw), welding, or the like.

Several embodiments and modification examples have been described above. However, the embodiment and the modification examples are not limited to the examples described above. For example, a plurality of embodiments may be implemented in combination with each other. The above-described embodiments can be implemented in various other forms, and various additions, omissions, substitutions, and changes can be made without departing from the concept of the present disclosure.

According to the present disclosure, assemblability can be improved.

### REFERENCE SIGNS LIST

1 Electrical connection unit
10 Electronic component
10X Electronic component
10Y Electronic component
10Z Electronic component
14 Attachment portion
14h Attachment hole
40 Routing board
40M Routing board
40X First routing board
40Y Second routing board
40Z Third routing board
41 Base plate (first base member, second base member)
42 Bus bar (first bus bar, second bus bar)
43 Fastening member
First positioning portion
45s First facing surface
46 Second positioning portion
46s Second facing surface
47 Insulating rib
51 Flat surface portion (first flat surface portion, second flat surface portion)
51a First surface
51b Second surface
51h Through-hole
51Xe First base end
51Ye Second base end
52 Fixing portion
52a Standing plate portion
52b Horizontal plate portion
52h Insertion hole
55 Accommodation portion
75 Coupling bus bar
80 Metal plate
80e1 First end
80e2 Second end
80e3 Third end
80e4 Fourth end
81 Flat surface portion
82 Fixing portion
82h Engagement hole
83 Fixing portion
83h Engagement hole
91 Insulating sheet
92 Heat transfer member
93 Insulating cover
93h Vent hole
111 Fastening member
112 Fastening member
MP Placement table
MU Main body
SU Subunit
SUX Subunit (first subunit)
SUY Subunit (second subunit)
SUZ Subunit

What is claimed is:

1. An electrical connection unit comprising:
a first subunit including
a plurality of first bus bars including portions disposed on the same plane, and
a first base member including a plate-shaped or sheet-shaped first flat surface portion holding the plurality of first bus bars, and a first positioning portion; and
a second subunit including
a plurality of second bus bars including portions disposed on the same plane, and
a second base member including a plate-shaped or sheet-shaped second flat surface portion holding the plurality of second bus bars, and a second positioning portion, wherein
the second subunit is electrically connected to the first subunit,
in a case where a thickness direction of the first flat surface portion is a first direction and a direction intersecting the first direction is a second direction,
the first positioning portion has a first facing surface extending in the first direction from a first base end of the first flat surface portion on the second subunit side, and
the second positioning portion has a second facing surface facing the first facing surface and extending in the first direction along the first facing surface from a second base end of the second flat surface portion on the first subunit side.

2. The electrical connection unit according to claim 1, wherein
the first base member further includes a fixing portion that stands from the first base end toward a side where the first facing surface extends in the first direction, and extends along the second flat surface portion from a standing end, and
the first facing surface protrudes more in the first direction than the fixing portion.

3. The electrical connection unit according to claim 1, further comprising
a metal plate to which the first subunit and the second subunit are fixed and that integrally holds the first subunit and the second subunit, wherein
the first facing surface extends from the first base end to a side opposite to the metal plate, and
the second facing surface extends from the second base end to the side opposite to the metal plate.

4. The electrical connection unit according to claim 1, wherein
the first positioning portion has a rectangular tube shape extending in the first direction with the first facing surface as a part of an outer peripheral surface.

5. The electrical connection unit according to claim 1, wherein
the first subunit further includes a plurality of electronic components electrically connected to the plurality of first bus bars, and an insulating rib extending between the plurality of electronic components, and
the first positioning portion is connected to an extending end of the insulating rib.

6. The electrical connection unit according to claim 1, further comprising
a pair of coupling bus bars electrically connecting the first subunit to the second subunit, wherein
the first positioning portion is disposed between the pair of coupling bus bars.
